(19) United States
(12) Patent Application Publication
(10) Pub. No.: US 2008/0042229 A1
(43) Pub. Date: Feb. 21, 2008

(54) Image Sensor and Method for Manufacturing the Same

(76) Inventor: Keun Hyuk Lim, Songpa-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/782,909

(22) Filed: Jul. 25, 2007

(30) Foreign Application Priority Data
Aug. 18, 2006 (KR) 10-2006-0078127

(51) Int. Cl. H01L 31/00; H01L 21/425

(52) U.S. Cl. 257/439; 438/527; 257/E21.474; 257/E31.001

(57) ABSTRACT

An image sensor is provided incorporating a first conductive type semiconductor substrate including an active area defined by a device isolation layer; a second conductive type first ion implant area formed as multiple regions in the active area; a second conductive type second ion implant area connecting the multiple regions of the second conductive type first ion implant area; and a first conductive type ion implant area formed on the second conductive type second ion implant area. The multiple regions of the second conductive type first ion implant area can be formed deeply in the substrate. The second conductive type second ion implant can be formed in the substrate at an upper region of the first ion implant area, a middle region of the first ion implant area, or a lower region of the first ion implant area.

### CROSS-REFERENCE TO RELATED APPLICATION

The present application claims the benefit under 35 U.S.C. §119 of Korean Patent Application No. 10-2006-0078127, filed Aug. 18, 2006, which is hereby incorporated by reference in its entirety.

### BACKGROUND

Generally, an image sensor is a semiconductor device that converts an optical image into an electrical signal. The image sensor is typically classified as a charge coupled device (CCD) image sensor or a Complementary Metal Oxide Silicon (CMOS) image sensor.

The CMOS image sensor utilizes a photodiode and transistors to convert an optical image into an electrical signal. Light incident on a photodiode generates electrons in a depletion area of the photodiode, and signals can be generated using the electrons.

The electrons generated in the depletion area are extracted from the photodiode through a reset process, and at this time, the whole of the photodiode should be depleted for resetting. This depletion is called being pinned.

However, according to the related art, when the pinning is not completely made, the depletion area where the electrons are generated becomes narrow so that sensitivity or saturation level becomes low. In addition, when the reset is not completely made, image lagging occurs.

In other words, with the image sensor according to the related art, when an ion implant area is too broadly distributed, the pinning is not appropriately accomplished and the depletion is not completely performed at the time of reset. Therefore, the depletion area capable of generating the electrons becomes narrow or the electrons are not completely reset, causing image lagging.

### BRIEF SUMMARY

Embodiments of the present invention provide an image sensor and a method for manufacturing the same, which incorporates implanting ions into an N-type ion implant area with a pattern in a lattice structure, so that a depletion area and a reset can be easily made, and making it possible to maximize the depletion of a photodiode.

Also, embodiments of the present invention provide an image sensor and a method for manufacturing the same, which incorporates implanting ions into an N-type ion implant area with a pattern in a lattice structure, so that a depletion area can more easily be made to reduce image lagging, making it possible to improve the characteristics of a photodiode.

An image sensor according to an embodiment comprises: a first conductive type semiconductor substrate including an active area defined by a device isolation layer; a second conductive type first ion implant area formed in multiple regions in the active area; a second conductive type second ion implant area connecting the multiple regions of the second conductive type first ion implant area; and a first conductive type ion implant area formed on the second conductive type second ion implant area.

Also, a method for manufacturing an image sensor according to an embodiment comprises: defining an active area by forming a device isolation layer on a first conductive type semiconductor substrate; forming a second conductive type first ion implant area divided into multiple regions in the active area; forming a second conductive type second ion implant area connecting the multiple regions of the second conductive type first ion implant area; and forming a first conductive type ion implant area on the second conductive type second ion implant area.

### BRIEF DESCRIPTION OF THE DRAWINGS

FIG. 1 is a cross-sectional view of an image sensor according to an embodiment.

FIGS. 2 and 4 to 5 are cross-sectional views showing a manufacturing process of an image sensor according to an embodiment.

FIGS. 3A and 3B are plan views of a photoresist pattern for a first ion implant area according to embodiments of the present invention.

FIG. 6 is a cross-sectional view showing depletion of an image sensor according to a first embodiment.

FIG. 7 is a cross-sectional view showing depletion of an image sensor according to a second embodiment.

FIGS. 8 and 9 are cross-sectional views of an image sensor according to embodiments of the present invention.

### DETAILED DESCRIPTION

Hereinafter, an image sensor and a method for manufacturing the same according to embodiments of the present invention will be described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

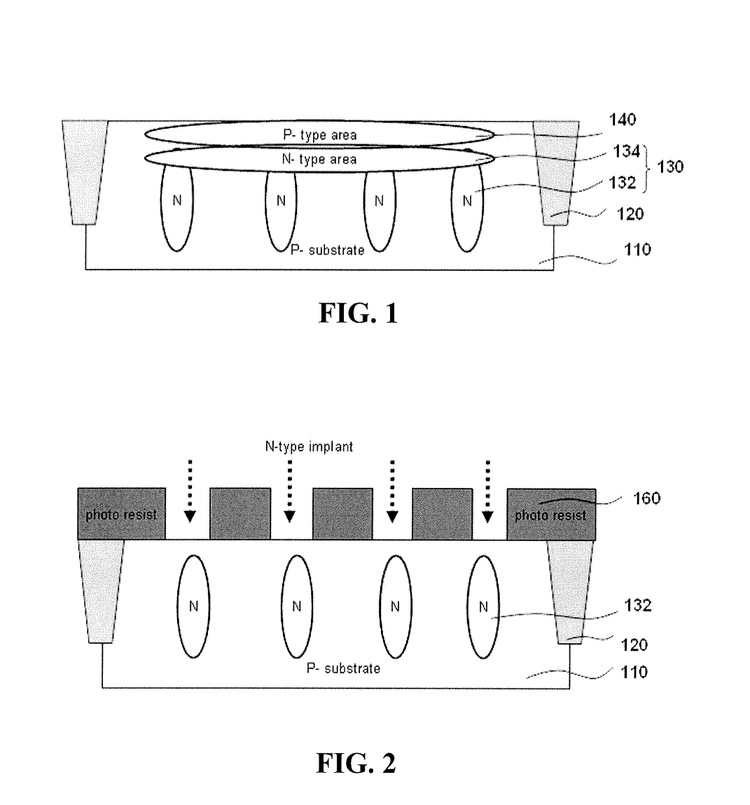

FIG. 1 is a cross-sectional view of an image sensor according to an embodiment.

The image sensor according to an embodiment includes a first conductive type semiconductor substrate 110, a second conductive type first ion implant area 132, a second conductive type second ion implant area 134, and a first conductive type ion implant area 140.

In one embodiment, the semiconductor substrate 110 is P-type, the second conductive type second ion implant area 134 is an N-type ion implant area, and the first conductive type ion implant area 140 is a P-type ion implant area, but embodiments are not limited thereto.

The first conductive type semiconductor substrate 110 has an active area defined by a device isolation layer 120. The first conductive type semiconductor substrate 110 can be a P-type semiconductor substrate. In an embodiment, the first conductive type semiconductor substrate 110 can be made by forming a P-type epitaxial on a Si wafer or forming a P-type well on a Si wafer by means of a multi ion implant.

The device isolation layer 120 can be formed, for example by means of a LOCOS or a Shallow Trench Isolation (STI) process.

Next, the second conductive type first ion implant region 132 can be formed in multiple regions in the active area. For example, as illustrated in FIG. 1, four second conductive type first ion implant areas 132 are shown, but embodiments are not limited thereto. Accordingly, the first ion implant 132 can be formed in multiple regions such as, for example, two, three, or five regions.

When the first conductive type semiconductor substrate 110 is P-type, the second conductive type first ion implant area 132 can be an N-type ion implant area.

The second conductive type first ion implant area 132 can be formed at a depth of 1,000 to 6,000 Å from a surface of the first conductive type semiconductor substrate 110. The first conductive type semiconductor substrate 110 exists in all directions around the second conductive type first ion implant areas 132 so that a depletion area effectively extends to all directions when the second conductive type first ion implant area 132 is depleted, making it possible to more easily make the pinning as compared to the related art.

Also, the second conductive type first ion implant area can be formed to a depth of 9,000 to 11,000 Å from the surface of the first conductive type semiconductor substrate 110. Here, the second conductive type first ion implant area is formed at a location deeper by twice or three times as compared to some related art while still being able to completely or substantially perform the pinning.

In other words, when the N-type ion implant area is thickly distributed in a vertical direction, the related art shows difficulty with the pinning in the center portion of the N-type ion implant area. However, according to embodiments of the present invention, although the thickness of the N-type ion implant area is deep, the pinning can be completely or substantially performed so that the depletion area of a photodiode becomes thick, and consequently, the number of electrons capable of being generated according to light increase, making it possible to improve sensitivity and further increase saturation.

The second conductive type second ion implant area 134 performs a function of coupling together the second conductive type first ion implant area 132 having the multiple regions by allowing the second conductive type first ion implant area 132 to be electrically connected to each other.

The second conductive type second ion implant area 134 is shown in FIG. 1 to be formed on the upper region of the second conductive type first ion implant area 132 by way of example, but embodiments are not limited thereto. For example, in other embodiments, the second conductive type second ion implant area 134 can be formed on the middle of the second conductive type first ion implant area 132 or formed in the lower of the second conductive type first ion implant area 132, making it possible to electrically couple the second conductive type first ion implant area 132.

Thereby, the second conductive type first ion implant area 132 and the second conductive type second ion implant area 134 form a second conductive type ion implant area 130.

The first conductive type ion implant area 140 is formed on the second conductive type second ion implant area 134. When the first conductive type semiconductor substrate 110 is P-type, the first conductive type ion implant area 140 can be a P-type ion implant area.

Accordingly, the depletion area of the N-type ion implant area of the photodiode can more easily be extended so that the pinning can easily be accomplished. Thereby, the reset operation is easily in operating the photodiode, making it possible to reduce image lagging.

### FIRST EMBODIMENT

FIGS. 2, 4 and 5 are cross-sectional views showing the manufacturing process of an image sensor according to a first embodiment.

The method for manufacturing the image sensor according to a first embodiment includes: defining an active area; forming a second conductive type first ion implant area; forming a second conductive type second ion implant area; and forming a first conductive type ion implant area.

The method for manufacturing the image sensor as described below involves a P-type semiconductor substrate, an N-type first and second ion implant area, and a P-type ion implant area, but embodiments are not limited thereto.

Referring to FIG. 2, an active area can be defined by forming a device isolation layer 120 on a first conductive type semiconductor substrate 110. The first conductive type semiconductor substrate 110 can be a P-type semiconductor substrate. In an embodiment, the first conductive type semiconductor substrate 110 can be made by forming a P-type epitaxial on a Si wafer or forming a P-type well on a Si wafer by means of a multi ion implant.

The device isolation layer 120 can be formed, for example, by means of a LOCOS process or a Shallow Trench Isolation (STI) process.

A first photoresist pattern 160 for the multiple regions of the first ion implant can be formed in the active area of the semiconductor substrate 110. The second conductive type first ion implant area 132 divided into multiple regions can be formed by implanting N-type ions using the first photoresist pattern 160 as a mask.

The second conductive type first ion implant area 132 can be formed beginning at a depth of 1,000 to a depth of 6,000 Å from the upper of the first conductive type semiconductor substrate 110.

The second conductive type first ion implant area 132 can be formed at a desired depth by implanting ions with an implantation energy of 80 to 200 KeV. In one embodiment, the ion implant begins at 80 KeV and then increases by 60 KeV increments to reach the implantation energy of 200 KeV, so that the second conductive type first ion implant area 132 can be formed at the depth of 1,000 to 6,000 Å in the first conductive type semiconductor substrate 110.

The first conductive type semiconductor substrate 110 exists all around the second conductive type first ion implant area 132 by enveloping each region so that a depletion area effectively extends to all directions when the second conductive type first ion implant area 132 is depleted, making it possible to more easily make the pinning as compared to the related art.

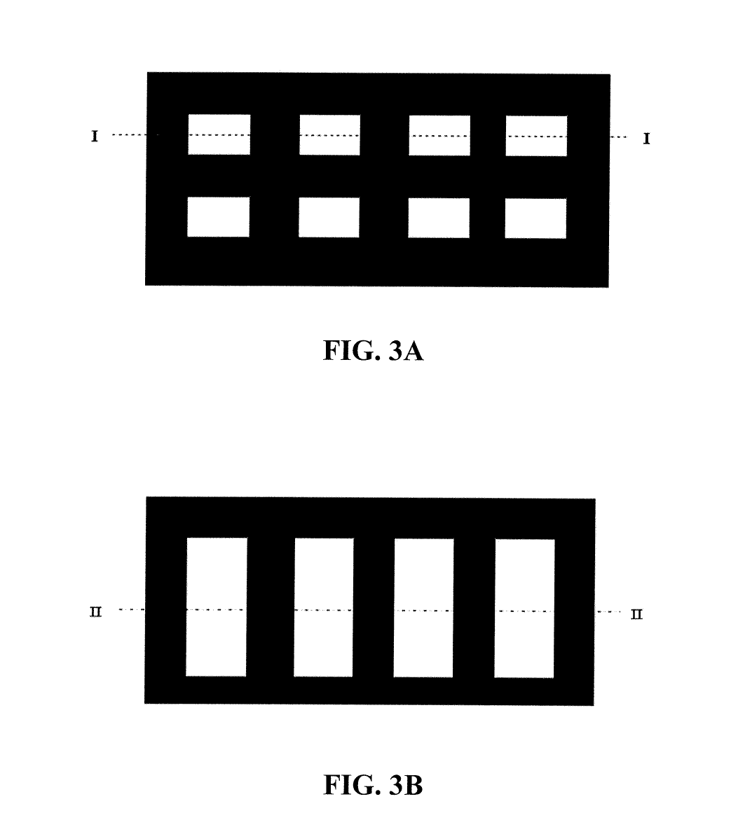

A mask for forming the first photoresist patterns 160 will be described with reference to FIGS. 3A to 3B.

As shown in FIGS. 3A and 3B, the first photoresist patterns 160 are indicated by the dark portion of the mask (in case of a positive photoresist film), and the second conductive type ion implant is made in the regions indicated by white portions of the mask in the subsequent process. In the case of a negative photoresist film, the pattern of the mask is the reverse thereof.

Line I-I or line II-II in FIGS. 3A and 3B can correspond to the shape of the cross-sectional view in FIG. 2.

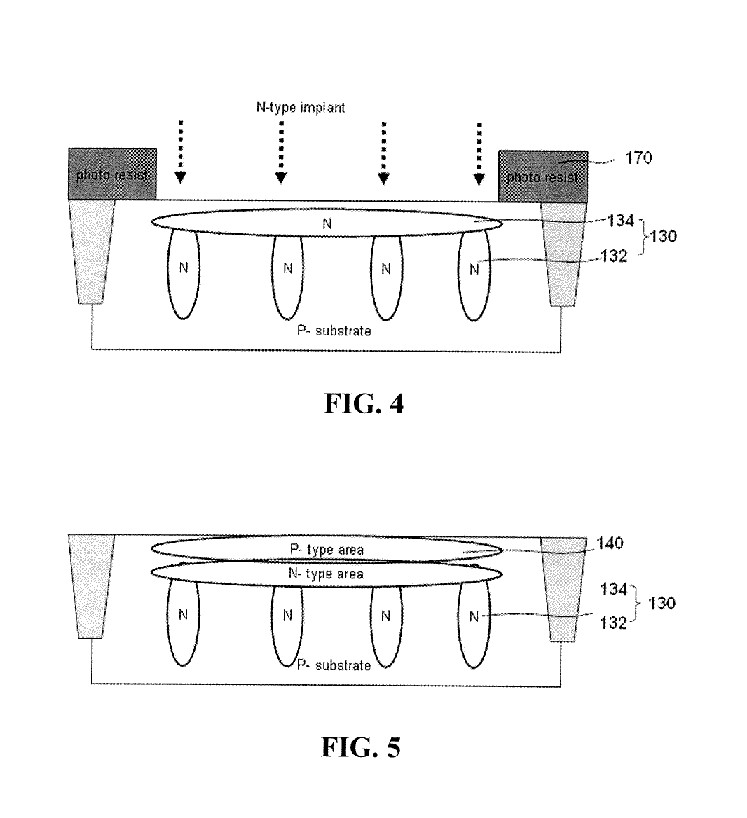

Next, as shown in FIG. 4, a second conductive type second ion implant area 134 connecting the second conductive type first ion implant areas 132 is formed.

A second photoresist pattern 170 exposing the active area of the semiconductor substrate 110 is formed. N-type ions are implanted into the substrate using the second photoresist pattern 170 as a mask to form the second conductive type second ion implant area 134 electrically coupling the multiple regions of the second conductive type first ion implant area 132.

In the first embodiment, the second conductive type second ion implant area 134 is described to be formed on an upper region of the second conductive type first ion implant area 132 by way of example, but embodiments are not limited thereto.

Next, referring to FIG. 5, a first conductive type ion implant area 140 is formed on the second conductive type second ion implant area 134. The first conductive type ion implant area 140 can be formed by implanting P-type ions using the second photoresist pattern 170 as a mask or by implanting P-type ions by newly forming a third photoresist pattern (not shown).

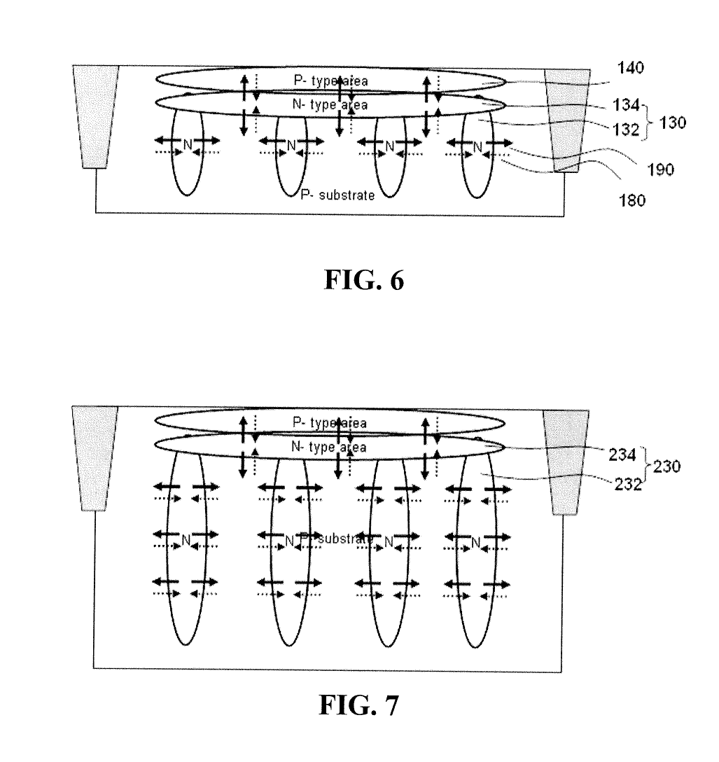

FIG. 6 is a cross-sectional view showing depletion of an image sensor according to a first embodiment.

A bias applied to the N-type ion implant area 130 of the image sensor extends the N-type depletion area (190), and both the P-area of the substrate 110 and the P-type ion implant area 140 neighboring the surface of the photodiode become a reverse shape allowing the P-type depletion area to extend (180) so that the depletion area in the upper region contacts the depletion area in the lower region, generating the phenomenon that the photodiode portion is entirely depleted.

In particular, a second conductive type first ion implant area 132 is formed in a lower region of the first conductive type semiconductor substrate 110 in a shape having multiple regions such that the first conductive type semiconductor substrate 110 surrounds each of the multiple regions in all directions, which allows the depletion area of the N-type ion implant area 132 of the photodiode to more easily be extended. Therefore, the pinning is easily performed so that the reset operation can be fully accomplished in operating the photodiode, making it possible to reduce the image lagging.

### SECOND EMBODIMENT

FIG. 7 is a cross-sectional view showing depletion of an image sensor according to a second embodiment.

The method for manufacturing the image sensor according to a second embodiment includes: defining an active area; forming a second conductive type first ion implant area; forming a second conductive type second ion implant area; and forming a first conductive type ion implant area.

The method for manufacturing the image sensor according to the second embodiment can adopt some features of the first embodiment.

According to the second embodiment, the second conductive type first ion implant 232 can be formed to a depth of 9,000 to 11,000 Å from the surface of the first conductive type semiconductor substrate 110.

The second conductive type first ion implant area 232 can be formed by implanting ions with an implantation energy of 80 to 800 KeV. In one embodiment, the ion implant begins using an implantation energy of 80 KeV and then the implantation energy increases to 800 KeV by increments of 60 KeV, so that the second conductive type first ion implant area 232 can be formed to the depth of 9,000 to 11,000 Å in the first conductive type semiconductor substrate 110.

With the method for manufacturing the image sensor according to the second embodiment, although the second conductive type first ion implant area 232 is formed in a location deeper by twice or three times as compared to some related art, the pinning can be completely or substantially accomplished.

In other words, when the N-type ion implant area is thickly distributed in a vertical direction, the related art shows difficulty with the pinning in the center portion of the N-type ion implant area. In contrast, for embodiments of the present invention, although the thickness of the N-type ion implant area is deep, the pinning can be completely or substantially accomplished so that the depletion area of a photodiode becomes thick and, consequently, the number of electrons capable of being generated according to light increase, making it possible to improve sensitivity and further increase saturation.

The second conductive type second ion implant area 234 is formed to connect the second conductive type first ion implant areas 232 so that it completes the second conductive type ion implant area 230 by electrically connecting the multiple regions of the second conductive type first ion implant area 232.

Thereafter, the first conductive type ion implant area can be formed on the second conductive type second ion implant area 234.

In the first embodiment and the second embodiment, the second conductive type second ion implant area 134 is described to be formed at an upper region of the second conductive type first ion implant area 132 by way of example, but embodiments are not limited thereto.

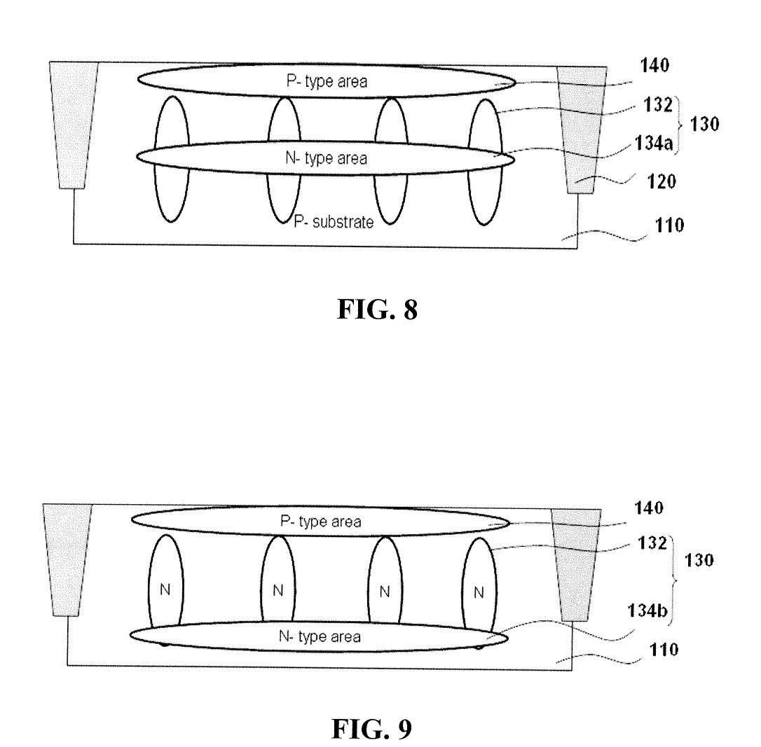

For example, as shown in FIG. 8, the second conductive type second ion implant area 134a can be formed at a middle region of the second conductive type first ion implant area 132.

In another embodiment, as shown in FIG. 9, the second conductive type second ion implant area 134b can be formed at a lower region of the second conductive type first ion implant area 132.

The embodiments as illustrated in FIGS. 8 and 9 can adopt the technical characteristics of the first embodiment or the second embodiment.

According to embodiments of the present invention, the depletion area of the N-type ion implant area of the photodiode can more easily be extended. Therefore, the pinning is easily performed so that the reset operation is easily accomplished in operating the photodiode, making it possible to reduce image lagging.

Also, according to the related art, when the N-type ion implant area is thickly distributed in a vertical direction, the pinning in the center portion of the N-type ion implant area has difficulty in completely being made. However, according to embodiments of the present invention, although the thickness of the N-type ion implant area may be deep, the pinning can completely be performed so that the depletion area of a photodiode becomes thick and, consequently, the number of electrons capable of being generated according to light increase, making it possible to improve sensitivity and further increase saturation.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a first conductive type semiconductor substrate including an active area defined by a device isolation layer;
a second conductive type first ion implant area formed as multiple regions in the active area;
a second conductive type second ion implant area connecting the multiple regions of the second conductive type first ion implant area; and
a first conductive type ion implant area formed on the second conductive type second ion implant area.

2. The image sensor according to claim 1, wherein the second conductive type first implant area is formed from a depth of 1,000 to 6,000 Å from a surface of the first conductive type semiconductor substrate.

3. The image sensor according to claim 1, wherein the second conductive type first implant area is formed to a depth of 9,000 to 11,000 Å in the first conductive type semiconductor substrate.

4. The image sensor according to claim 1, wherein the second conductive type second ion implant area is formed on an upper region of the second conductive type first ion implant area.

5. The image sensor according to claim 1, wherein the second conductive type second ion implant area is formed on a middle region of the second conductive type first ion implant area.

6. The image sensor according to claim 1, wherein the second conductive type second ion implant area is formed on a lower region of the second conductive type first ion implant area.

7. The image sensor according to claim 1, wherein the first conductive type is P-type and the second conductive type is N-type.

8. The image sensor according to claim 1, wherein the multiple regions of the second conductive type ion implant area are spaced apart at regular intervals.

9. A method for manufacturing an image sensor comprising:
defining an active area by forming a device isolation layer on a first conductive type semiconductor substrate;
forming a second conductive type first ion implant area comprising multiple regions in the active area;
forming a second conductive type second ion implant area connecting the multiple regions of the second conductive type first ion implant area; and
forming a first conductive type ion implant area on the second conductive type second ion implant area.

10. The method according to claim 9, wherein forming the second conductive type first ion implant area comprises:
forming a first photoresist pattern on the first conductive type semiconductor substrate exposing multiple regions of a photodiode area; and
implanting second conductive type ions into the photodiode area using the first photoresist pattern as a mask.

11. The method according to claim 9, wherein the second conductive type first implant area is formed from a depth of 1,000 to 6,000 Å in the first conductive type semiconductor substrate.

12. The method according to claim 11, wherein forming the second conductive type first ion implant area comprises:
implanting second conductive type ions using an implantation energy of 80 to 200 KeV.

13. The method according to claim 12, wherein implanting second conductive type ions using an implantation energy of 80 to 200 KeV comprises beginning an ion implant at an implantation energy of 80 KeV and then increasing the implantation energy to 200 KeV by increments of 60 KeV.

14. The method according to claim 9, wherein the second conductive type first ion implant area is formed to a depth of 9,000 to 11,000 Å in the first conductive type semiconductor substrate.

15. The method according to claim 14, wherein forming the second conductive type first ion implant area comprises:
implanting second conductive type ions using an implantation energy of 80 to 800 KeV.

16. The method according to claim 15, wherein implanting second conductive type ions using an implantation energy of 80 to 800 KeV comprises beginning an ion implant at an implantation energy of 80 KeV and then increasing the implantation energy to 800 KeV by increments of 60 KeV.

17. The method according to claim 9, wherein the second conductive type second ion implant area is formed on an upper region of the second conductive type first ion implant area.

18. The method according to claim 9, wherein the second conductive type second ion implant area is formed on a middle region of the second conductive type first ion implant area.

19. The method according to claim 9, wherein the second conductive type second ion implant area is formed on a lower region of the second conductive type first ion implant area.

20. The method according to claim 9, wherein the first conductive type is P-type and the second conductive type is N-type.
